(19) United States
(12) Patent Application Publication
(10) Pub. No.: US 2009/0223538 A1
(43) Pub. Date: Sep. 10, 2009

(54) Method for Cleaning a Workpiece With the Aid of Halogen Ions

(76) Inventors: Ursus Krüger, Berlin (DE); Uwe Pyritz, Berlin (DE); Heike Schiewe, Berlin (DE); Raymond Ullrich, Schönwalde (DE)

Correspondence Address: SIEMENS CORPORATION;INTELLECTUAL PROPERTY DEPARTMENT, 170 WOOD AVENUE SOUTH, ISELIN, NJ, 08830, US

(21) Appl. No.: 11/792,658

(22) PCT Filed: Nov. 29, 2005
(86) PCT No.: PCT/EP05/56301

§ 371 Date: Jun. 8, 2007

(30) Foreign Application Priority Data
Dec. 10, 2004 (DE) 10 2004 061 269.2

(51) Int. Cl. B08B 6/00; H01L 21/306

(52) U.S. Cl. 134/1.1; 156/345.1

(57) ABSTRACT

The invention relates to a method for cleaning turbine blades, for example, in a cleaning chamber into which a process gas containing especially fluoride ions is introduced. According to the inventive method, contaminated process gas is directed into an analysis chamber where a plasma is ignited and is analyzed using emission spectroscopy in order to monitor the process, particularly to determine the conditions for stopping the process. The spectrometric measurement can be evaluated in an evaluation unit, the cleaning process being stopped via signal line in case of a characteristic change of the spectrum. Also disclosed is a cleaning device comprising an analysis apparatus with a sample chamber and a plasma generator, an interface being provided for evaluating the result of the analysis.

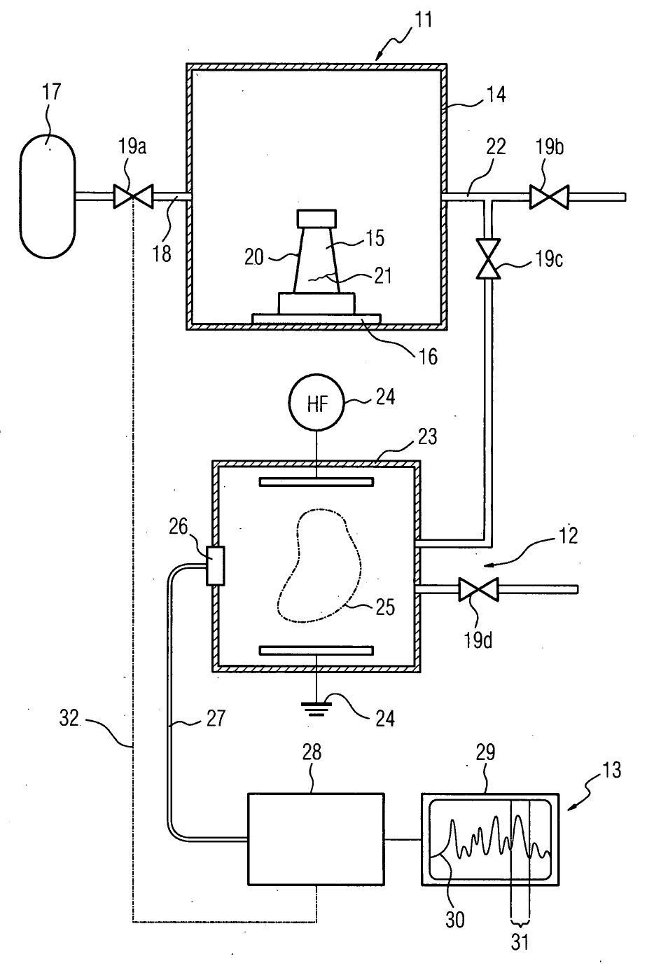

### CROSS REFERENCE TO RELATED APPLICATIONS

This application is the US National Stage of International Application No. PCT/EP2005/056301, filed Nov. 29, 2005 and claims the benefit thereof. The International Application claims the benefits of German application No. 10 2004 061 269.2 filed Dec. 10, 2004, both of the applications are incorporated by reference herein in their entirety.

### FIELD OF INVENTION

The invention relates to a method for cleaning a workpiece of corrosive products in a reactive atmosphere with the aid of halogen ions, in which the workpiece is exposed in a cleaning chamber to a process gas that contains the halogen ions, the process gas being supplied and removed to/from the cleaning chamber continuously or at time intervals.

### BACKGROUND OF THE INVENTION

A method of this kind can be found for example in EP 209 307 A1. According to this method, a turbine blade for example, which has reached the end of its envisaged life, is secured as the workpiece to be cleaned in the cleaning chamber and a process gas, which contains halogen ions, in particular fluoride ions, is supplied to the cleaning chamber. The process parameters that should be set here are based on empirical values which have been collected by repeated cleaning of turbine blades. According to EP 209 307 A1 the cleaning process in the chamber can be carried out for example at a temperature of 950° C. over a cleaning period of 3 hours.

The described cleaning process is particularly suitable for workpieces made from what are known as superalloys, as are used for turbine blades. These workpieces are frequently also provided with coatings, for example with thermal protective layers, also called Thermal Barrier Coatings (TBC) and anti-corrosive layers which contain chromium, aluminum and yttrium and are also called MCrAlY layers. In the case of spent turbine blades even said layers are attacked by the formation of corrosive products, so these layers likewise have to be removed during a cleaning process. In particular, complex carbonate and oxide compounds form from the alloy elements of said layers and the turbine blades forming the substrate material and these compounds have to be removed from the substrate material. The calcium-magnesium-aluminum-silicon oxide system (CMAS) in particular should be mentioned here. A further group is formed by the thermally grown oxides (TGO). Said layers and contaminants are converted into volatile substances by means of an attack by halogen ions in a reactive atmosphere, thus cleaning the turbine blades. In particular this is brought about by what is known as Fluoride Ion Cleaning (FIC). At the end of the cleaning process the turbine blades can be recoated and supplied to a further lifecycle.

Owing to the high complexity of contaminants the cleaning process that is based on empirical values must be analyzed at the end of the empirically determined cleaning time by way of suitable analysis of the cleaned workpiece (turbine blades). Complete cleaning of the surface may thus be ensured since this forms a compulsory requirement for successful re-coating. The cleaning process must potentially be repeated or lengthened.

### SUMMARY OF INVENTION

An object of the invention lies in disclosing a method for cleaning workpieces with the aid of halogen ions with which the workpieces may be completely cleaned in an optimally short time.

This object is achieved according to the invention with the method described in the introduction in that at least some of the removed process gas is supplied to an analysis cell, in which analysis cell plasma is ignited in the process gas with predefined process parameters and the plasma is spectrometrically analyzed. Spectrometric analysis of the process gas in the described manner advantageously allows a direct conclusion to be made about the course of the cleaning process proceeding in the cleaning chamber. The determined spectrum can for example be an emission spectrum of electromagnetic radiation emitted by the components in the plasma.

A different or additional possibility lies in connecting a mass spectrometer to the analysis cell with which a mass spectrum of the components in the plasma can be determined. Components for analysis may be split further by the plasma in the analysis cell, so a higher resolution is attained with the determined mass spectra.

In any case evaluation of the spectrometric analysis result allows a conclusion to be made about the composition of the process gas in the analysis device. This composition allows a further conclusion to be drawn about which cleaning products are produced by the cleaning process, so the cleaning process can be continued until complete cleaning of the workpiece may be concluded owing to the absence of spectral lines of the characteristic cleaning products. The cleaning process can be terminated immediately after this analysis result has been produced.

With the method according to the invention the cleaning time can be advantageously optimized for each workpiece to be cleaned. Recourse to empirical values can be omitted thereby, whereby, on the one hand, in the case of workpieces in which cleaning can be carried out more quickly than is made obvious by the empirical value, the cleaning time can be reduced and in the case of workpieces which are still not completely cleaned after the cleaning time according to an empirical value the process time can be automatically adjusted, so repeated cleaning steps can be omitted. Each workpiece is therefore cleaned in the optimum time, whereby, overall, the cleaning process is advantageously more economical because when determining an empirical value a safety allowance would also always be required for the cleaning time in order to also detect as far as possible the cases in which a longer than average cleaning time is necessary.

Execution of the method according to the invention can be further optimized by determining empirical values which allow correct interpretation of the determined spectra. To determine these empirical values, according to an advantageous embodiment of the method the method can be used to correlate a change in the determined spectra of the process gas with the progress during cleaning of the workpiece. This means that in this embodiment of the method the temporal course of the changes in the respectively determined spectra and the cleaning process that proceeds on the surface of the workpiece or even in possible cracks in the workpiece is monitored. The correlation between the two procedures can be interpreted to find clear characteristics in the spectra which signal a successful conclusion to the cleaning process. For the purpose of interpretation it is advantageously expedient to document the cleaning progress and the determined spectra as a function of the elapsed cleaning time.

Documentation can take place for example by visually monitoring the surface of the workpiece during cleaning. This has the advantage that visual monitoring can take place in the cleaning chamber, as can determination of the spectra in the analysis chamber, without the cleaning process being interrupted, so, on the one hand the cleaning process is advantageously not disrupted by analysis and, on the other hand, monitoring does not cause any time delays in the process sequence.

A further possibility of detecting the cleaning progress lies in that fact that workpiece samples are taken at intervals during the cleaning process. For this purpose the workpiece should expediently be in several parts as early as at the start of cleaning, so a plurality of samples can be taken during the cleaning process. If a sluice is provided for the taking of samples, samples can advantageously be taken without interrupting the cleaning process. A further possibility lies in removing the samples inside the cleaning chamber only from the sphere of action of the reactive atmosphere, so the cleaning process is stopped. Once the cleaning process has finished all workpiece samples may be evaluated together.

Samples can be taken for example whenever characteristic changes occur in the recording of the. spectra (for example disappearance of a specific spectral line). This result may thus be directly correlated with the cleaning progress on the corresponding workpiece sample. Particular attention can be paid in the process to the spectral lines that are produced as a result of oxygen and carbon, since disappearance of these lines can be regarded as evidence that carbonate and oxide compounds have been completely broken down.

The correlation of the cleaning progress with the change in determined spectra can advantageously also be used to obtain knowledge about the cleaning process beyond the occurrence of successful cleaning. By way of example specific spectral lines can be used as evidence of certain contaminants, whereby adjustment of the process parameters is possible to optimize the cleaning process. Empirical values may therefore be advantageously obtained which allow optimization of the cleaning processes, so the required cleaning time can be shortened in addition to being precisely determined.

Once the parts of the spectrum relevant to the assessment of the cleaning process have been determined, according to a particular embodiment of the invention the method can be carried out in such a way that the spectrometric analysis is carried out by using a correlation filter with which a correlation between the workpiece liberated from corrosive products and a change in the respectively determined spectrum, characteristic of complete removal of the corrosive products, is selected. By using a correlation filter it is advantageously possible to weight parts of the spectrum that are relevant to the assessment of the cleaning process more strongly, so simple measures for process control may be derived from the determination thereof. In particular the condition required for concluding the cleaning process may be determined more easily. The condition can be used manually or automatically to interrupt the cleaning process.

According to one embodiment of the correlation filter this can only let through a bandwidth of the spectrum in which the characteristic change occurs. The filter can consist for example of a grid filter which only lets through the bandwidth that is to be visually assessed and is constructed for example as a type of window in the wall of the cleaning chamber. Use of a correlation filter of this type is advantageously very inexpensive, whereby the data set to be evaluated is also reduced, so the electronic evaluation device also advantageously inexpensively requires a low capacity.

Of course it is also possible that the determined spectrum is subject to electronic data processing (for example Fourier transformation) for correlation filtering. The determined result of analysis is in each case hereby processed in such a manner that the characteristic change in the spectrum is more obvious.

The invention also refers to a cleaning device with a cleaning chamber for a workpiece and with an inlet and an outlet for a process gas for the cleaning procedure.

This cleaning device is likewise described in EP 209 307 A1 already mentioned in the introduction. It is particularly suitable for carrying out the method mentioned in the introduction.

The object of the invention is therewith to also disclose a cleaning device for a cleaning chamber for a workpiece with which improved control of the cleaning process is possible.

This object is achieved with said cleaning device in that an analysis cell for the process gas is connected to the outlet which is equipped with a plasma generator and which comprises an interface for spectrometric analysis of plasma ignited in the process gas. The cleaning device therewith has all the requirements necessary for carrying out the method already described. The analysis cell has a suitable extraction point for removing the contaminated process gas, thereby allowing real time analysis. The plasma generator in the analysis cell allows ignition of the plasma, it being possible for the spectrometric analysis to take place by way of a suitable analysis device for which a suitable interface is made available. In the case of an emission spectrometric analysis this can consist for example of a “window” in the analysis cell that can be penetrated by the wavelengths being analyzed.

### BRIEF DESCRIPTION OF THE DRAWINGS

Further details of the invention will be described hereinafter with reference to the drawing. The single FIGURE schematically shows the construction of an exemplary embodiment of the cleaning device according to the invention which is capable of carrying out an exemplary embodiment of the method according to the invention. The exemplary embodiment of the method according to the invention should be carried out with the aid of the illustrated device.

### DETAILED DESCRIPTION OF INVENTION

According to the FIGURE a cleaning device 11 is provided to which an analysis cell 12 is connected for the process gas that is used in the cleaning device 11, the analysis cell 12 being connected to an evaluation device 13.

The cleaning device 11 comprises a cleaning chamber 14 in which a workpiece 15 in the form of a turbine blade is placed in a receptacle 16. A process gas can be supplied to the cleaning chamber 14 from a storage container 17 via an inlet 18 by opening a valve 19a. The process gas contains halogen ions, in particular fluoride ions, which liberate a surface 20 of the workpiece 15, including an inner surface of cracks that may possibly exist in the workpiece, of corrosive products and possible coating residues. The contaminated process gas is then removed from the cleaning chamber 14 via an outlet 22 by opening a valve 19b.

The cleaning process is only shown schematically. Instead of the storage container 17 a plurality of storage containers may also be disposed, mixing being performed via suitable valves (not shown). Pumps (not shown) for conveying the process gas or possibly evacuating the cleaning chamber 14 can also be provided. A heater (not shown) can also advantageously be disposed in the cleaning chamber 14.

The process gas can be continuously supplied or removed through the valves 19a, 19b, and this causes a constant turnover of process gas in the cleaning chamber 14. The valves 19a, 19b can be used as regulators in this case. A further possibility is discontinuous supply or removal of process gas. In this case the valves 19a, 19b are alternately opened and closed, resulting in a more or less continuous cleaning process. Process gas can be removed from the outlet 22 at regular intervals by opening a valve 19c and be supplied to a chamber 23 of the analysis cell 12. With a more or less continuous progression of the cleaning process, process gas can be removed whenever the valve 19b to remove the contaminated process gas is opened. Sample taking during the course of the cleaning process is thus possible online without interrupting the cleaning process itself.

In the chamber 23 plasma 25 is ignited in the process gas disposed in the chamber 23 by means of a plasma generator 24. The plasma emits electromagnetic radiation which can be fed through a type of window 26, which forms an interface for the emission spectrometric analysis, into a fiber optic 27. The fiber optic guides the light into a processor 28 in which data processing can take place, the result of analysis being output at a screen 29.

The window 26 can for example consist of a grid filter which is used as a correlation filter in such a way that only wavelength ranges of plasma emissions essential to analysis are let through. The window is provided with a diamond-like protective coating on the side facing the interior of the chamber 23, so it is not affected by the reactivity of the plasma.

A characteristic range 31 is schematically illustrated in an emission spectrum 30 shown on the screen 29, the range characteristically changing at the conclusion of the cleaning process and thus being used as a decision criterion for an end to the cleaning process. The evaluation device sends a signal via a control line 32 to the valve 19a which is closed to end the cleaning procedure. In a manner not illustrated the evaluation device can also have further control lines to the valves 19b and 19b or, for removing the analyzed process gas, to a valve 19d as well. This functionality can, however, also be implemented in a separate control device (not shown).

1. A process for removing a removal region (10), in particular a corrosion product (10),of a component (1), in which the removal region (10), prior to final cleaning, is pretreated in such a way that the removal region (10) is damaged, by a larger attackable surface area being produced by a salt attack, in particular by a fused salt, so that then a material-removal rate during the final cleaning of the removal region (10) is greater than without the damage to the removal region (10), the salt sodium sulfate (Na₂SO₄) and/or cobalt sulfate (COSO₄) being used for the salt attack.

2. The process as claimed in claim 1, characterized in that
the damage to the removal region (10) is produced in such a manner as to produce a larger attackable surface area.

3. The process as claimed in claim 1, 2 or 3, characterized in that
cracks (25, 31), which damage the removal region (10), are produced in the removal region (10).

4. The process as claimed in claim 1, characterized in that
delaminations (34) are produced between the removal region (10) in layer form and a surface (13) on which the removal region (10) is arranged.

5. The process as claimed in claim 1, 2, 3, 4, 6 or 7, characterized
in that a material (16) is applied to the removal region (10) in order to damage the removal region (10), and in that the material (16) is applied in the form of a slurry.

6. The process as claimed in claim 1, 2, 3, 4, 6 or 7, characterized in that
a material (16) is applied to the removal region (10) in order to damage the removal region (10), and in that the material (16) is laid on the removal region (10) in the form of a sheet.

7. The process as claimed in claim 8 or 9, characterized in that
the material (16) which is present on the removal region (10) is heated.

8. The process as claimed in claim 10, characterized in that
the component (1) is heated, in particular only locally in the removal region (10).

9. The process as claimed in claim 10 or 11, characterized in that
the heating of the material (16), in particular the local heating, is effected by a light source, in particular by a laser (19).

10. The process as claimed in claim 10 or 11, characterized in that
the heating, in particular the local heating, is generated by electromagnetic induction.

11. The process as claimed in claim 10 or 11, characterized in that
the heating, in particular the local heating, is generated by means of microwaves.

12. The process as claimed in claim 1, characterized in that
the removal region (10) is a corrosion product, and in that the process removes the corrosion products (10) aluminum oxide (Al₂O₃) and/or cobalt oxide (CoO₂) and/or titanium oxide (TiO₂).

13. The process as claimed in claim 1, 2, 3, 4 or 5, characterized in that
the damage to the removal region (10) is effected by sand-blasting.

14. The process as claimed in claim 1, 2, 3, 4 or 5, characterized in that
the damage to the removal region (10) is effected by a thermal shock.

15. The process as claimed in claim 17, characterized in that
the thermal shock is generated by at least partial melting and subsequent cooling of the removal region (10).

16. The process as claimed in claim 18, characterized in that
the melting is effected by a laser (28).

17. The process as claimed in claim 1, characterized in that
a fluoride ion cleaning (FIC) of the component (1) is carried out as the final cleaning in order to completely remove the removal region (10).

18. The process as claimed in claim 20, characterized in that
in one of the final process steps, the damaged removal region (10) is completely removed by an acid treatment.

19. The process as claimed in claim 1, characterized in that
the removal region (10) is present on a metallic substrate (4).

20. The process as claimed in claim 22, characterized in that
the substrate (4) is a nickel-base, cobalt-base or iron-base superalloy.

21. The process as claimed in claim 1, characterized in that
the removal region (10) is present as a layer on an MCrAlX layer,
where M stands for at least one element selected from the group consisting of iron, cobalt or nickel,
and X stands for yttrium and/or at least one rare earth element.

22. The process as claimed in claim 1 or 23, characterized in that
the removal region (10) is metallic.

23. The process as claimed in claim 1 or 23, characterized in that
the removal region (10) is ceramic.

24. The process as claimed in claim 1, 24 or 25, characterized in that
the metallic removal region (10), in particular as a layer, includes corrosion products.

25. The process as claimed in claim 1, characterized in that
the component (1) is a component (1) of a gas turbine (100) or steam turbine (300, 300), in particular a rotor blade or guide vane (120, 130) or a combustion chamber lining (155).

26. The process as claimed in claim 1 or 26, characterized in that
the process is carried out on a component (1) which is to be refurbished.
